(19) United States
(12) Patent Application Publication
(10) Pub. No.: US 2026/0158948 A1
(43) Pub. Date: Jun. 11, 2026

(54) CHARGING EQUIPMENT FOR ELECTRIC VEHICLES

(71) Applicant: LITE-ON TECHNOLOGY CORPORATION, Taipei (TW)

(72) Inventors: I-Hsin LIU, Taipei (TW); Wei-Hsiang CHEN, Taipei (TW)

(21) Appl. No.: 19/033,520

(22) Filed: Jan. 22, 2025

(30) Foreign Application Priority Data
Dec. 11, 2024 (CN) 202423055205.8

(51) Int. Cl. B60L 53/30; B60L 53/16; B60L 53/18; H02J 7/00; H05K 5/03

(52) U.S. Cl. CPC B60L 53/30; B60L 53/16; B60L 53/18; H05K 5/03; H02J 7/70

(57) ABSTRACT

A charging equipment for electric vehicles is provided. The charging equipment includes a charging connector, a charger and a cable connected between the charging connector and the charger. The charger includes a panel, housing assembly and a shielding structure. The panel is disposed on the housing assembly. The shielding structure includes a base and an shielding portion. The base is disposed between the panel and the housing assembly. The shielding portion protrudes from the panel.

This application claims the benefit of People's Republic of China application Serial No. 202423055205.8, filed Dec. 11, 2024, the subject matter of which is incorporated herein by reference.

### BACKGROUND

### Technical Field

The present disclosure relates to a charging equipment, and more particularly to a charging equipment for electric vehicles.

### Description of the Related Art

As electric vehicles become more popular, the demand for charging equipment for electric vehicles is gradually increasing. Generally, the charging equipment includes a charging connector, a charger, and a cable connected between the charging connector and the charger. When the charging equipment is not in use, the charging connector can be disposed on the charger. When the charging equipment is in use, the user can remove the charging connector from the charger and connect the charging connector with the electric vehicle to charge the electric vehicle. Some types of charging connectors include buttons, and the user can press the button to remove the charging connector from the charger. However, in a cold environment, the button of the charging connector may freeze and become inoperable, which causes a lot of inconvenience and does not meet the needs.

### SUMMARY

The present disclosure provides a charging equipment for electric vehicles, and the charging equipment includes a shielding structure to prevent the button of the charging connector from freezing.

According to some embodiments, a charging equipment for electric vehicles is provided. The charging equipment includes a charging connector, a charger and a cable connected between the charging connector and the charger. The charger includes a panel, a housing assembly and a shielding structure. The panel is disposed on the housing assembly. The shielding structure includes a base and a shielding portion. The base is disposed between the panel and the housing assembly. The shielding portion protrudes from the panel.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic view of a charging equipment according to an embodiment of the present disclosure.

FIG. 2 illustrates a schematic exploded view of the charging equipment according to an embodiment of the present disclosure.

FIG. 3 illustrates a schematic view of the assembly of some components of the charging equipment according to an embodiment of the present disclosure.

### DETAILED DESCRIPTION

Various embodiments will be described more fully hereinafter with reference to accompanying drawings. For clarity, the elements may not be drawn to scale. The specification and the drawings are to be regarded as an illustrative sense rather than a restrictive sense. The illustration uses the same/similar reference numerals to indicate the same/similar elements. Moreover, use of ordinal terms such as “first”, “second”, “third”, etc., in the specification and claims to modify an element does not by itself imply any priority, precedence, or order of one claim element over another, but are used merely as labels to distinguish one claim element having a certain name from another element having the same name (but for use of the ordinal term) to distinguish the claim elements.

As used in the specification and the appended claims, spatial relation terms such as “on”, “above”, “over”, “upper,” “top”, “below”, “beneath”, “under”, “lower” and “bottom” be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

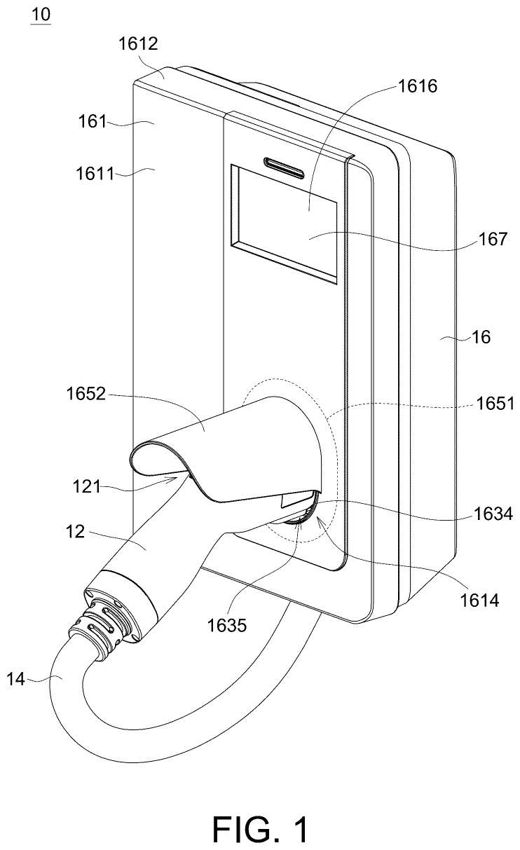

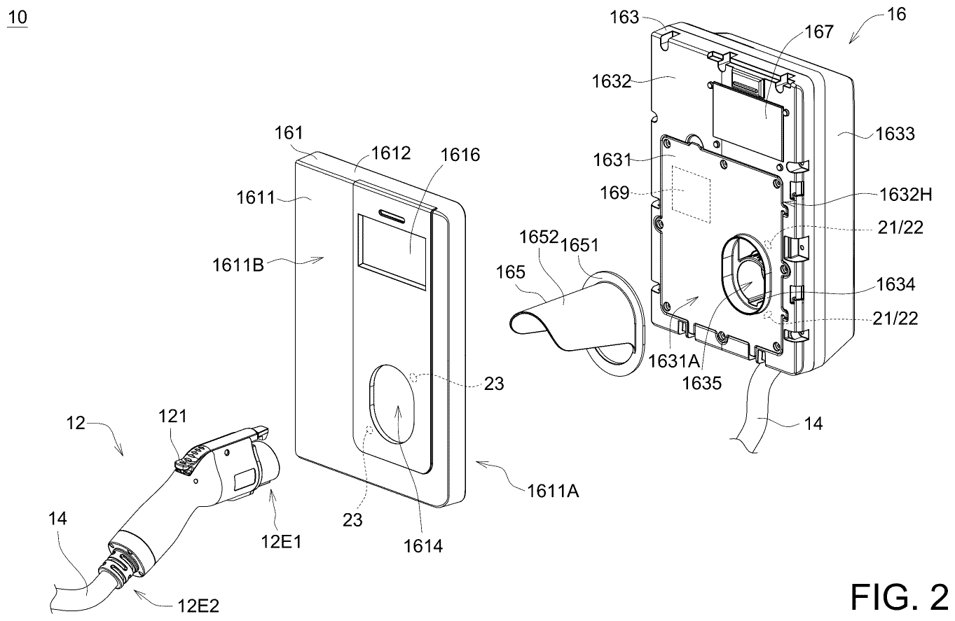

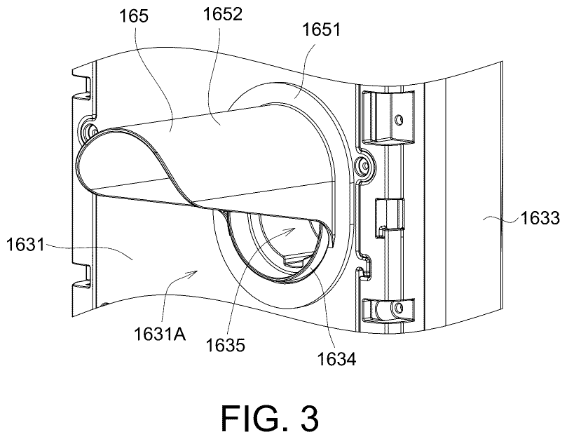

Referring to FIGS. 1 to 3, FIG. 1 illustrates a schematic view of a charging equipment 10 according to an embodiment of the present disclosure, FIG. 2 illustrates a schematic exploded view of the charging equipment 10 according to an embodiment of the present disclosure, and FIG. 3 illustrates a schematic view of the assembly of some components of the charging equipment 10 according to an embodiment of the present disclosure. The charging equipment 10 can be used to charge electric vehicles (not shown). The charging equipment 10 includes a charging connector 12, a cable 14 and a charger 16. The cable 14 is connected between the charging connector 12 and the charger 16. The charging connector 12 includes a button 121. The charging connector 12 has a first end 12E1 and a second end 12E2 different from the first end 12E1. The second end 12E2 of the charging connector 12 can be used to connect the cable 14. The first end 12E1 of the charging connector 12 can be used to connect the charging port of the electric vehicle so as to charge the electric vehicle. The first end 12E1 of the charging connector 12 may include pins corresponding to the charging port of the electric vehicle so as to electrically connect the charging connector 12, the cable 14 and the charger 16 to the electric vehicle. The charger 16 provides power to the electric vehicle through the cable 14 and the charging connector 12. When the charging equipment 10 is not in use, the charging connector 12 can be disposed on the charger 16. The button 121 of the charging connector 12 can be used to release the connection between the charging connector 12 and the charger 16. The charging connector 12 can be a charging connector based on the J1772 standard maintained by SAE International, but the present disclosure is not limited thereto. The charging connector 12 can be any type of charging connector. The charger 16 includes a panel 161, a housing assembly 163 and a shielding structure 165. The panel 161 is disposed on the housing assembly 163. The shielding structure 165 includes a base 1651 and a shielding portion 1652. The base 1651 is disposed between the panel 161 and the housing assembly 163. The shielding portion 1652 protrudes from the panel 161.

The panel 161 includes a panel body 1611 and an edge portion 1612. The edge portion 1612 surrounds the panel body 1611. The panel body 1611 has a first surface 1611A and a second surface 1611B opposite to the first surface 1611A. The first surface 1611A of the panel body 1611 faces the housing assembly 163. The second surface 1611B of the panel body 1611 faces the outside of the charging equipment 10. The second surface 1611B of the panel body 1611 may face the user. The edge portion 1612 can protrude from the first surface 1611A of the panel body 1611. The edge portion 1612 can extend from the first surface 1611A of the panel body 1611 toward the housing assembly 163. The panel body 1611 can include a through hole 1614. FIGS. 1 and 2 show that the through hole 1614 is oval, but the present disclosure is not limited thereto. The through hole 1614 may be in any shape such as square, rectangular, circular, or polygonal. The through hole 1614 can be extended from the first surface 1611A of the panel body 1611 to the second surface 1611B. The panel 161 can be attached or fixed to the housing assembly 163 through fasteners such as screws (not shown). The attachment between the panel 161 and the housing assembly 163 can be released by removing the fasteners; that is, the panel 161 can be detachably disposed on the housing assembly 163. In other embodiments, the panel 161 can be attached to the housing assembly 163 through a snap-fit structure, and the attachment between the panel 161 and the housing assembly 163 can be released by controlling the snap-fit structure. In other embodiments, the panel 161 can be attached to the housing assembly 163 through a hinge, and the panel 161 can rotate relative to the housing assembly 163.

The housing assembly 163 can include a cover 1631, a frame structure 1632, a housing 1633, a limit element 1634 and a recess 1635. The frame structure 1632 is disposed on the housing 1633. The frame structure 1632 can be attached or fixed to the housing 1633. The frame structure 1632 can include an access hole 1632H. The cover 1631 is disposed on the frame structure 1632 and covers the access hole 1632H. The shape and size of the cover 1631 can match the shape and size of the access hole 1632H. The cover 1631, the frame structure 1632 and the housing 1633 can define an accommodation space. For example, the cover 1631 can be attached or fixed to the frame structure 1632 through screws, and the attachment between the cover 1631 and the frame structure 1632 can be released by removing the screws; alternatively, the cover 1631 can be attached or fixed to the frame structure 1632 through a hinge, and the cover 1631 can rotate relative to the frame structure 1632 to expose the access hole 1632H. The access hole 1632H can be used to examine and/or repair and/or replace the components of the charger 16. The size and shape of the cover 1631 are not limited to those shown in FIG. 2.

The cover 1631 has a surface 1631A facing the first surface 1611A of the panel body 1611. The limit element 1634 is disposed on the surface 1631A of the cover 1631. The limit element 1634 protrudes from the surface 1631A of the cover 1631. The recess 1635 is recessed from the surface 1631A of the cover 1631 toward the housing 1633. The limit element 1634 can surround the opening of the recess 1635. The recess 1635 is used to accommodate the charging connector 12. When the charging equipment 10 is not in use, the first end 12E1 of the charging connector 12 can be inserted into the recess 1635. When the charging equipment 10 is not in use, the first end 12E1 of the charging connector 12 can engage with the recess 1635. The button 121 of the charging connector 12 can be used to release the engagement between the charging connector 12 and the recess 1635 of the charger 16. For example, the user can press the button 121 of the charging connector 12 to release the engagement between the charging connector 12 and the recess 1635 of the charger 16, and then pull the charging connector 12 from the recess 1635.

The charger 16 can include a supply circuit 169. The supply circuit 169 can be disposed inside the housing assembly 163. The supply circuit 169 can be disposed in the accommodation space defined by the cover 1631, the frame structure 1632 and the housing 1633. The supply circuit 169 can be electrically connected to an external power source. The supply circuit 169 can be electrically connected to the cable 14 to provide power to the electric vehicle through the cable 14 and the charging connector 12.

The shielding portion 1652 of the shielding structure 165 protrudes from the base 1651. The base 1651 of the shielding structure 165 can have an annular structure. The shielding portion 1652 can be disposed on an inner edge of the annular structure of the base 1651. The shielding portion 1652 may be bent along at least a portion of the inner edge of the annular structure of the base 1651. As shown in FIG. 3, the shielding structure 165 is disposed on the surface 1631A of the cover 1631. The base 1651 of the shielding structure 165 surrounds the limit element 1634 so that the movement of the shielding structure 165 along the surface 1631A of the cover 1631 can be limited by the limit element 1634, which prevents the shielding structure 165 from shaking and/or falling. Moreover, when the shielding structure 165 is to be mounted on the surface 1631A of the cover 1631, the limit element 1634 can be used to guide the mounting position so that the shielding structure 165 can be easily positioned in the correct position. The size and shape of the inner edge of the annular structure of the base 1651 can match the size and shape of the limit element 1634. The shielding portion 1652 may surround at least a portion of the limit element 1634. As shown in FIG. 1, the through hole 1614 of the panel body 1611 of the panel 161 can surround the limit element 1634. The shielding portion 1652 passes through the through hole 1614 and protrudes from the panel 161. The panel body 1611 of the panel 161 may cover the base 1651 to prevent the shielding structure 165 from loosening or falling. The size and shape of the through hole 1614 can match the size and shape of the limit element 1634.

As shown in FIG. 1, when the charging equipment 10 is not in use, the charging connector 12 can pass through the through hole 1614 and the base 1651 to be disposed in (or to engage with) the recess 1635, and the shielding portion 1652 can cover the button 121 of the charging connector 12. In a cold environment, the shielding portion 1652 covering the button 121 of the charging connector 12 can prevent the button 121 from freezing and becoming inoperable.

The shielding structure 165 of the present disclosure is detachable. That is, the user can detach or mount the shielding structure 165 as needed. In an embodiment, as shown in FIG. 2, the charging equipment 10 includes one or more magnetic elements 21. The one or more magnetic elements 21 can be disposed adjacent to the limit element 1634. The one or more magnetic elements 21 may surround the limit element 1634. The magnetic elements 21 can be separately from each other. The one or more magnetic elements 21 may be embedded in the cover 1631. The position of the one or more magnetic elements 21 may correspond to the position of the base 1651 of the shielding structure 165. The base 1651 of the shielding structure 165 can be attached to the surface 1631A of the cover 1631 through magnetic force provided by the one or more magnetic elements 21, and the shielding structure 165 can be detachably disposed on the surface 1631A of the cover 1631 through the one or more magnetic elements 21. The magnetic element 21 may have any shape and any size. For example, the magnetic element 21 can be round, ring-shaped, square, sector-shaped, or strip-shaped.

In an embodiment, as shown in FIG. 2 the charging equipment 10 includes one or more fastening elements 22. The one or more fastening elements 22 can be disposed adjacent to the limit element 1634. The one or more fastening elements 22 may surround the limit element 1634. The fastening elements 22 can be separately from each other. The one or more fastening elements 22 may pass through the base 1651 of the shielding structure 165 and the cover 1631 so that the shielding structure 165 can be fastened to the cover 1631 of the housing assembly 163 through the one or more fastening elements 22. For example, the fastening element 22 is a screw. The shielding structure 165 can be detachably disposed on the surface 1631A of the cover 1631 through the one or more fastening elements 22.

In an embodiment, as shown in FIG. 2 the charging equipment 10 includes one or more snap-fit elements 23. The one or more snap-fit elements 23 can be disposed on the first surface 1611A of the panel body 1611. The snap-fit elements 23 can be separately from each other. The position of the one or more snap-fit elements 23 can correspond to the position of the base 1651 of the shielding structure 165. The base 1651 of the shielding structure 165 can be attached to the panel 161 through the one or more snap-fit elements 23, so that the shielding structure 165 can be detachably disposed on the first surface 1611A of the panel body 1611 through the one or more snap-fit elements 23.

The shielding structure 165 can be easily detached and mounted with the use of the magnetic element(s) 21 and/or fastening element(s) 22 and/or snap-fit element(s) 23.

In an embodiment, the charger 16 can include a display screen 167 disposed between the housing assembly 163 and the panel 161, and the panel body 1611 of the panel 161 can include a display window 1616; the position of the display screen 167 can correspond to the position of the display window 1616. The display screen 167 can be used to display information, such as whether charging is ready, the battery level of the electric vehicle, charging time, power consumption and other information. The user can view the information shown on the display screen 167 through the display window 1616. FIGS. 1 and 2 show that the display screen 167 and the display window 1616 are rectangular, but the present disclosure is not limited thereto. The display screen 167 and the display window 1616 can be in any shape such as square, circular, oval or polygonal.

The present disclosure provides a charging equipment for electric vehicles with a shielding structure. The shielding structure can prevent the button of the charging connector from freezing, and the problem of being unable to operate the charging equipment due to the freezing of the button of the charging connector can be solved. The base of the shielding structure is disposed between the panel and the housing assembly, which can achieve the effects of being difficult to loosen and preventing theft. Moreover, the shielding structure is detachable; when there is no need to use the shielding structure (such as in a non-cold environment), the user can detach the shielding structure to meet various environments and needs. As such, the present disclosure can be adapted to various environments and needs. During the mounting of the shielding structure, the use of the limit element, magnetic element(s), fastening element(s), and snap-fit element(s) can assist in positioning the shielding structure, and thus it is easy to detach and mount the shielding structure.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A charging equipment for electric vehicles, comprising:
a charging connector;
a charger comprising a panel, a housing assembly and a shielding structure, wherein the panel is disposed on the housing assembly, the shielding structure includes a base and a shielding portion, the base is disposed between the panel and the housing assembly, and the shielding portion protrudes from the panel; and
a cable connected between the charging connector and the charger.

2. The charging equipment according to claim 1, wherein the housing assembly comprises a recess and a limit element, the recess is used to accommodate the charging connector, and the limit element surrounds the opening of the recess.

3. The charging equipment according to claim 2, wherein the base of the shielding structure surrounds the limit element.

4. The charging equipment according to claim 2, wherein the charging connector engages with the recess, the charging connector comprises a button used to release the engagement between the charging connector and the recess, and the shielding portion of the shielding structure covers the button.

5. The charging equipment according to claim 2, wherein the panel comprises a through hole surrounding the limit element, and the charging connector passes through the through hole and the base to engage with the recess.

6. The charging equipment according to claim 1, wherein the base has an annular structure, and the shielding portion is disposed on an inner edge of the annular structure and bent along at least a portion of the inner edge.

7. The charging equipment according to claim 1, wherein the housing assembly comprises a cover, a frame structure and a housing, the frame structure is disposed on the housing and comprises an access hole, and the cover is disposed on the frame structure and covers the access hole.

8. The charging equipment according to claim 7, wherein the shielding structure is detachably disposed on a surface of the cover.

9. The charging equipment according to claim 7, wherein the housing assembly comprises a recess and a limit element, the recess is used to accommodate the charging connector, the recess is recessed from a surface of the cover toward the housing, and the limit element surrounds the recess and protrudes from the surface of the cover.

10. The charging equipment according to claim 9, further comprising magnetic elements embedded in the cover and surrounding the limit element, and the base of the shielding structure is attached to the surface of the cover through magnetic force provided by the magnetic elements.

11. The charging equipment according to claim 7, further comprising a magnetic element disposed in the cover, and the base of the shielding structure is attached to a surface of the cover through magnetic force provided by the magnetic element.

12. The charging equipment according to claim 1, further comprising a snap-fit element, the panel has a surface facing the housing assembly, the snap-fit element is disposed on the surface of the panel, and the shielding structure is attached to the panel through the snap-fit element.

13. The charging equipment according to claim 1, further comprising a fastening element, wherein the shielding structure is fastened to the housing assembly through the fastening element.

14. The charging equipment according to claim 1, wherein the charger comprises a display screen disposed between the housing assembly and the panel.

15. The charging equipment according to claim 1, wherein the charger comprises a supply circuit disposed inside the housing assembly, the supply circuit is electrically connected to the cable to provide power to the electric vehicles through the cable and the charging connector.

16. The charging equipment according to claim 1, wherein the panel comprises a through hole, and the shielding portion passes through the through hole and protrudes from the panel.

17. The charging equipment according to claim 1, wherein the panel comprises a panel body and an edge portion protruding from the panel body, and the panel body covers the base.

18. The charging equipment according to claim 17, wherein the panel body comprises a through hole, and the shielding portion passes through the through hole and protrudes from the panel.
